(19) United States
(12) Patent Application Publication
(10) Pub. No.: US 2025/0108582 A1
(43) Pub. Date: Apr. 3, 2025

(54) RESIN COMPOSITION, PREPREG, FILM WITH RESIN, SHEET OF METAL FOIL WITH RESIN, METAL-CLAD LAMINATE, AND PRINTED WIRING BOARD

(71) Applicant: Panasonic Intellectual Property Management Co., Ltd., Osaka (JP)

(72) Inventors: Yuichi ISHIKAWA, Fukushima (JP); Hiroharu INOUE, Osaka (JP)

(73) Assignee: Panasonic Intellectual Property Management Co., Ltd., Osaka (JP)

(21) Appl. No.: 18/832,666

(22) PCT Filed: Jan. 12, 2023
(86) PCT No.: PCT/JP2023/000640

§ 371 Date: Jul. 24, 2024

(30) Foreign Application Priority Data
Jan. 28, 2022 (JP) 2022-012410

(51) Int. Cl. B32B 15/08

(52) U.S. Cl. CPC B32B 15/08; B32B 2250/02; B32B 2260/046; B32B 2264/105; B32B 2305/076; B32B 2307/206; B32B 2379/08; B32B 2457/08

(57) ABSTRACT

A resin composition contains: a molybdenum compound (A); a curable resin (B) including a maleimide compound (B1) and an allyl-group-containing benzoxadine compound (B2); and an inorganic filler (C). The molybdenum compound (A) includes molybdenum compound particles to be surface-treated with a surface treatment agent.

### TECHNICAL FIELD

The present disclosure generally relates to a resin composition, a prepreg, a film with resin, a sheet of metal foil with resin, a metal-clad laminate, and a printed wiring board. More particularly, the present disclosure relates to a resin composition containing a curable resin, a prepreg, a film with resin, a sheet of metal foil with resin, a metal-clad laminate, and a printed wiring board.

### BACKGROUND ART

Patent Document 1 discloses a resin composition containing a molybdenum compound (A), an epoxy resin (B), a curing agent (C), and an inorganic filler (D). The inorganic filler (D) has a Mohs hardness equal to or greater than 3.5. The content of the inorganic filler (D) is 40-600 parts by mass with respect to 100 parts by mass in total of resin solid components.

On the other hand, Patent Document 2 discloses a resin composition containing a surface-treated molybdenum compound powder (A), an epoxy resin (B), a curing agent (C), and an inorganic filler (D).

Patent Documents 1 and 2 emphasize that their resin composition has excellent low thermal expansibility, heat resistance, and drillability. Not only these characteristics but also adhesive strength are important as well.

### CITATION LIST

### Patent Literature

Patent Document 1: WO 2012/099162 A1
Patent Document 2: WO 2013/047203 A1

### SUMMARY OF INVENTION

An object of the present disclosure is to provide a resin composition, a prepreg, a film with resin, a sheet of metal foil with resin, a metal-clad laminate, and a printed wiring board, all of which contribute to forming a cured product with excellent low thermal expansibility, heat resistance, adhesive strength, and drillability.

A resin composition according to an aspect of the present disclosure contains: a molybdenum compound (A); a curable resin (B) including a maleimide compound (B1) and an allyl-group-containing benzoxadine compound (B2); and an inorganic filler (C). The molybdenum compound (A) includes molybdenum compound particles to be surface-treated with a surface treatment agent.

A prepreg according to another aspect of the present disclosure includes: a base member; and a resin layer including either the resin composition described above or a semi-cured product of the resin composition, each of which is impregnated into the base member.

A film with resin according to still another aspect of the present disclosure includes: a resin layer including either the resin composition described above or a semi-cured product of the resin composition; and a supporting film supporting the resin layer thereon.

A sheet of metal foil with resin according to still another aspect of the present disclosure includes: a resin layer including either the resin composition described above or a semi-cured product of the resin composition; and a sheet of metal foil bonded to the resin layer.

A metal-clad laminate according to yet another aspect of the present disclosure includes: an insulating layer including either a cured product of the resin composition described above or a cured product of the prepreg described above; and a metal layer bonded to the insulating layer.

A printed wiring board according to yet another aspect of the present disclosure includes: an insulating layer including either a cured product of the resin composition described above or a cured product of the prepreg described above; and conductor wiring formed on the insulating layer.

### BRIEF DESCRIPTION OF DRAWINGS

FIG. 1 is a schematic cross-sectional view illustrating a prepreg according to an exemplary embodiment of the present disclosure;

FIG. 2 is a schematic cross-sectional view illustrating a film with resin according to the exemplary embodiment of the present disclosure;

FIG. 3 is a schematic cross-sectional view illustrating a sheet of metal foil with resin according to the exemplary embodiment of the present disclosure;

FIG. 4 is a schematic cross-sectional view illustrating a metal-clad laminate according to the exemplary embodiment of the present disclosure; and

FIG. 5 is a schematic cross-sectional view illustrating a printed wiring board according to the exemplary embodiment of the present disclosure.

### DESCRIPTION OF EMBODIMENTS

### 1. Overview

As described above, the resin compositions of Patent Documents 1 and 2 still have room for improvement at least in terms of adhesive strength. Thus, the present inventors carried out extensive research and development to provide a resin composition with excellent adhesive strength without causing a decline in low thermal expansibility, heat resistance, or drillability. As a result, the present inventors conceived the concept of a resin composition having the following structure.

Specifically, a resin composition according to this embodiment contains a molybdenum compound (A), a curable resin (B), and an inorganic filler (C). In particular, the molybdenum compound (A) includes molybdenum compound particles to be surface-treated with a surface treatment agent. The curable resin (B) includes a maleimide compound (B1) and an allyl-group-containing benzoxadine compound (B2).

According to this embodiment, letting the resin composition contain all of these components enables forming a cured product with excellent low thermal expansibility, heat resistance, adhesive strength, and drillability.

As used herein, the “heat resistance” may be rated by glass transition temperature (Tg). The “adhesive strength” as used herein specifically refers to the adhesive strength to a metal layer (such as a sheet of copper foil). The “drillability” as used herein may be rated by hole position accuracy. Specific methods for evaluating the respective characteristics will be described in detail later in the “Examples” section.

### 2. Details

### (1) Resin Composition

### (1.1) Chemical Makeup

A resin composition according to this embodiment contains a molybdenum compound (A), a curable resin (B), and an inorganic filler (C). The resin composition preferably further contains at least one of core-shell rubber (D) or a high-molecular-weight substance (E). Optionally, the resin composition may further contain other components (F). The respective components will be described one by one below.

### <Molybdenum Compound (A)>

The molybdenum compound (A) includes molybdenum compound particles. The molybdenum compound particles are surface-treated (surface-modified) with a surface treatment agent. That is to say, the molybdenum compound (A) includes a plurality of molybdenum compound particles. Each of the molybdenum compound particles has at least a part of its surface treated with a surface treatment agent. Having the molybdenum compound particles included in the molybdenum compound (A) surface-treated with the surface treatment agent in this manner enables increasing the adhesive strength of a cured product of the resin composition.

As used herein, the “surface treatment agent” refers to an agent that may change at least one of adhesion, adhesiveness, reactivity, or compatibility with other substances by changing the properties of the surface of a certain substance. For example, surface treatment agents include a coupling agent such as a silane coupling agent.

Also, the expression “the molybdenum compound (A) includes molybdenum compound particles (to be) surface-treated with a surface treatment agent” as used herein has two meanings.

One of the two meanings is that the molybdenum compound (A) includes molybdenum compound particles that have already been surface-treated with a surface treatment agent. This meaning is included on the supposition that pretreatment method (premixing method) may be adopted while the resin composition is being manufactured.

The other meaning is that the molybdenum compound particles have not been surface-treated yet, but the molybdenum compound (A) includes molybdenum compound particles which may be surface-treated with a surface treatment agent also included in the resin composition along with the molybdenum compound (A). This meaning is included on the supposition that an integral blending method may be adopted while the resin composition is being manufactured.

Examples of the molybdenum compound (A) include, without limitation, zinc molybdate, molybdenum dioxide, molybdenum trioxide, and calcium molybdate.

The molybdenum compound (A) preferably includes spherical particles. As used herein, the “spherical” refers to not only a perfect sphere (true sphere) but also an imperfect sphere which may be substantially identified with a true sphere. For example, spherical particles include particles preferably having an average circularity equal to or greater than 0.7, more preferably equal to or greater than 0.8. As for the molybdenum compound (A), “spherical particles” or “particles” herein refer to molybdenum compound particles.

The average circularity may be determined in the following manner. First, a powder containing particles, of which the average circularity is going to be determined, is shot with a scanning electron microscope. Next, using an image analyzer, the projected area (S) of the particles and the projected perimeter (L) of the particles are calculated based on the image thus shot, and the circularity is calculated by the formula “circularity=4πS/L².” The circularity is calculated for 100 arbitrary particles, and their average value is regarded as the average circularity.

Letting the molybdenum compound (A) include such spherical particles may improve the moldability of the resin composition. Optionally, the molybdenum compound (A) may include particles with a non-spherical shape.

The 50% volume average particle size (D50) of the molybdenum compound (A) is preferably equal to or greater than 0.1 μm and equal to or less than 2.0 μm, and more preferably equal to or greater than 0.1 μm and equal to or less than 1.0 μm. As used herein, the “50% volume average particle size” refers to a particle size (D50) at an integrated value of 50% in a particle size distribution measured using a particle size analyzer by a laser scattering/diffraction method.

The 90% volume average particle size (D90) of the molybdenum compound (A) is preferably equal to or less than 1.5 μm, more preferably equal to or less than 1.3 μm. As used herein, the “90% volume average particle size” refers to a particle size (D90) at an integrated value of 90% in a particle size distribution measured using a particle size analyzer by the laser scattering/diffraction method.

The surface treatment agent preferably includes at least one compound selected from the group consisting of fluorene compounds, phenylamino silane compounds, styryl silane compounds, triphenylphosphine compounds, methacrylic silane compounds, epoxy silane compounds, isocyanate compounds, vinyl silane compounds, and silicone compounds. This allows a cured product of the resin composition to have further increased adhesive strength. Note that all of the compounds listed above are silane coupling agents.

The fluorene compound herein refers to a compound having a fluorene skeleton. The fluorene compound is surface-modified by having the fluorene skeleton bonded to the surface of the molybdenum compound (A) particles at two points, thus allowing the particles of the molybdenum compound (A) to be dispersed with good stability in the resin composition. The fluorene compound preferably includes, without limitation, at least one selected from the group consisting of 9,9-bis[3-(triC1-4alkoxysilylC2-4alkylthio) propoxyphenyl]fluorene and 9,9-bis[3-(triC1-4alkoxysilylC2-4alkylthio) propoxy-C1-4alkylphenyl]fluorene. This allows a cured product of the resin composition to have further increased adhesive strength.

### <Curable Resin (B)>

The curable resin (B) contains a maleimide compound (B1) and an allyl-group-containing benzoxazine compound (B2). This allows the cured product of the resin composition to have increased heat resistance. The curable resin (B) may further contain a phenolic resin (B3).

The maleimide compound (B1) herein refers to a compound having at least one five-membered ring (maleimide group) in which maleic acid turns into imide. Examples of the maleimide compound (B1) include, without limitation, a compound expressed by the following Formula (b1-1), a compound expressed by the following Formula (b1-2), a compound expressed by the following Formula (b1-3), a compound expressed by the following Formula (b1-4), and a compound expressed by the following Formula (b1-5).

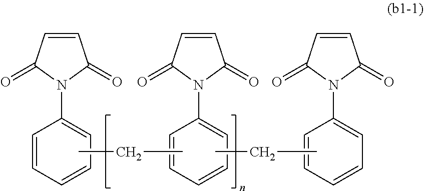

where n is an integer of 0 to 3.

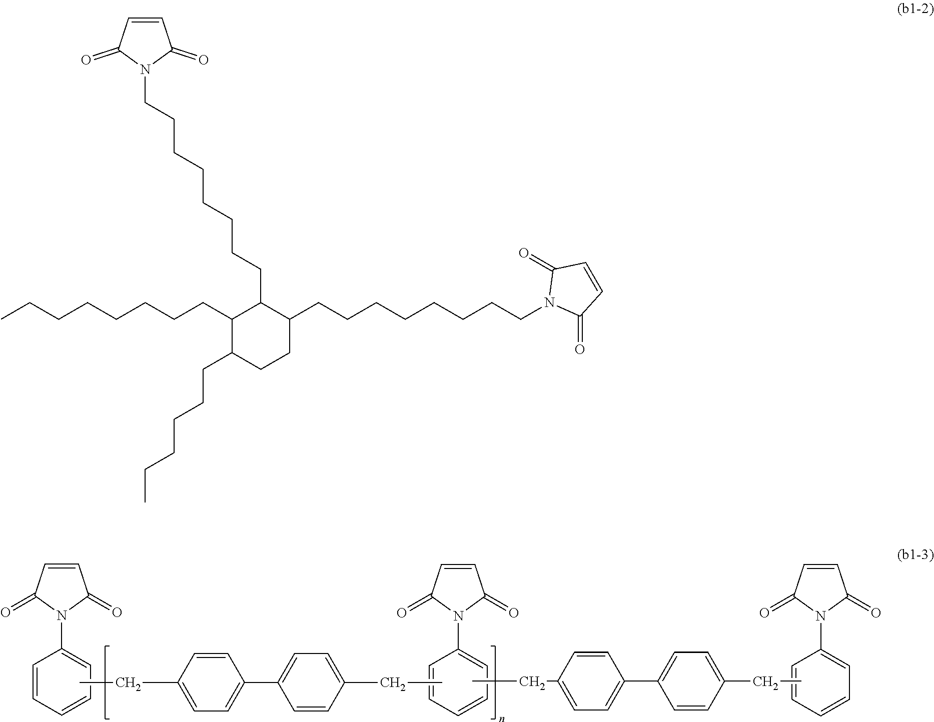

where n is an integer of 0 to 4.

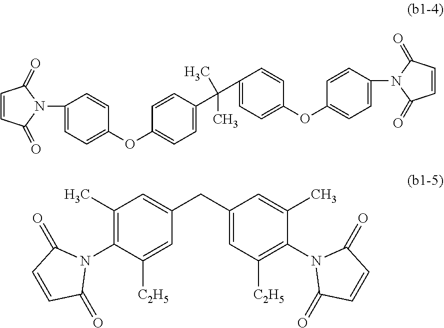 [SMILES: CC(C)(c1ccc(Oc2ccc(N3C(=O)C=CC3=O)cc2)cc1)c1ccc(Oc2ccc(N3C(=O)C=CC3=O)cc2)cc1 ; CCc1cc(Cc2cc(C)c(N3C(=O)C=CC3=O)c(CC)c2)cc(C)c1N1C(=O)C=CC1=O]

The allyl-group-containing benzoxazine compound (B2) is a benzoxazine compound having at least one allyl group. A benzoxazine compound herein refers to a compound having at least one benzoxazine ring.

Examples of the allyl-group-containing benzoxazine compound (B2) include, without limitation, a benzoxazine compound having the structure expressed by the following Formula (b2-1), a benzoxazine compound having the structure expressed by the following Formula (b2-2), and a benzoxazine compound having the structure expressed by the following Formula (b2-3).

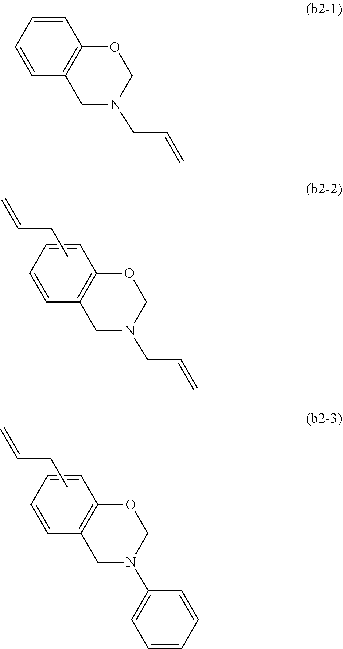

The ratio by mass (B2/B1) of the allyl-group-containing benzoxazine compound (B2) to the maleimide compound (B1) is preferably equal to or greater than 0.3 and equal to or less than 1.0, and more preferably equal to or greater than 0.35 and equal to or less than 0.8. Setting the ratio by mass (B2/B1) at a value equal to or greater than 0.3 may reduce the chances of causing a decline in adhesive strength to a metal layer (such as a sheet of copper foil). This may also reduce the chances of causing a decline in drillability. Setting the ratio by mass (B2/B1) at a value equal to or less than 0.1 may reduce the chances of causing a decline in glass transition temperature (Tg).

Examples of the phenolic resin (B3) include, without limitation, novolac phenolic resins, naphthalene phenolic resins, biphenyl-aralkyl phenolic resins, and dicyclopentadiene phenolic resins.

If the curable resin (B) includes the phenolic resin (B3), then the content of the phenolic resin (B3) is preferably equal to or less than 10 parts by mass, more preferably equal to or less than 7 parts by mass, with respect to 100 parts by mass of the curable resin (B).

### <Inorganic Filler (C)>

The inorganic filler (C) is effective in increasing dimensional stability. That is to say, adding the inorganic filler (C) to the resin composition makes it easier to decrease the coefficient of thermal expansion of a cured product of the resin composition.

Examples of the inorganic filler (C) preferably include, without limitation, at least one compound selected from the group consisting of silica, talc, boehmite, magnesium hydroxide, aluminum oxide, and tungsten compounds.

The 50% volume average particle size (D50) of the inorganic filler (C) is preferably equal to or greater than 0.1 μm and equal to or less than 2.0 μm, and more preferably equal to or greater than 0.1 μm and equal to or less than 0.6 μm.

Note that in this embodiment, the inorganic filler (C) does not include the molybdenum compound (A).

### <Core-Shell Rubber (D)>

The core-shell rubber (D) is an aggregate of rubber particles, and each rubber particle has a core-shell multilayer structure. Each rubber particle is made up of a core and a shell. At least one of the core or the shell has elasticity. Adding such core-shell rubber (D) to the resin composition enables increasing the impact resistance, thermal shock resistance, and drillability of the cured product without sacrificing the heat resistance.

Preferably, the core-shell rubber (D) contains silicone in at least one of the core or shell thereof. This may further enhance the thermal shock resistance. In other words, the impact resistance may be enhanced even at lower temperatures than in a situation where silicone is not included.

The core may contribute to increasing the toughness of the cured product of the resin composition. The core is rubber in the shape of a particle. The rubber may be either a copolymer or a homopolymer, whichever is appropriate. Examples of the polymer that forms the core may include, without limitation, silicone/acrylic polymers, acrylic polymers, silicone polymers, butadiene polymers, and isoprene polymers.

The shell is easily compatible with the curable resin (B) and may contribute to increasing the adhesive strength. The shell is present on the surface of the core. The shell is made up of multiple graft chains. One end of each graft chain is bonded to the surface of the core to form a fixed end, and the other end of the graft chain is a free end. The graft chain may be a copolymer or a homopolymer, whichever is appropriate. Examples of the polymer that forms the shell include, without limitation, acrylic copolymers, polymethyl methacrylate, and polystyrene.

The 50% volume average particle size (D50) of the core-shell rubber (D) is preferably equal to or greater than 0.01 μm and equal to or less than 0.5 μm, and more preferably equal to or greater than 0.05 μm and equal to or less than 0.3 μm. Setting the 50% volume average particle size (D50) of the core-shell rubber (D) at a value equal to or greater than 0.01 μm enables further enhancing the impact resistance of the cured product. Setting the 50% volume average particle size (D50) of the core-shell rubber (D) at a value equal to or less than 0.5 μm makes it easier for the core-shell rubber (D) to be dispersed uniformly in the resin composition, and therefore, dispersed uniformly in the cured product as well.

### <High-Molecular-Weight Substance (E)>

The high-molecular-weight substance (E) preferably contains at least one selected from the group consisting of acrylic resins, styrene copolymers, and butadiene copolymers. The styrene copolymer is a copolymer produced by polymerizing two or more types of monomers including a styrene monomer.

The acrylic resin preferably has the structure expressed by the following Formulae (1), (2) and (3).

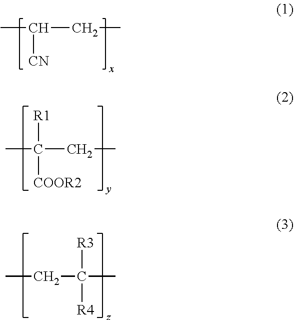

In these Formulae (1) to (3), x, y, and z represent mole fractions, and satisfy x+y+z≤1, 0<x≤0.2, 0.6≤y≤0.95, and 0.05≤z≤0.2.

In the Formula (2), R1 is either a hydrogen atom or a methyl group, and R2 includes at least one of a glycidyl group or an epoxidized alkyl group, which is selected from the group consisting of a hydrogen atom, an alkyl group, the glycidyl group and the epoxidized alkyl group.

In the Formula (3), R3 is either a hydrogen atom or a methyl group, and R4 is Ph (phenyl group), —COOCH₂Ph, or —COO(CH₂)₂Ph.

The main chain of the acrylic resin preferably has at least one structure expressed by the Formula (1), at least one structure expressed by the Formula (2), and at least one structure expressed by the Formula (3).

If the main chain of the acrylic resin has the structures respectively expressed by the Formulae (1), (2), and (3), the structures expressed by the Formulae (1), (2), and (3) may be arranged in any order without limitation. In this case, on the main chain of the acrylic resin, the structures expressed by the Formula (1) may or may not be continuous with each other, the structures expressed by the Formula (2) may or may not be continuous with each other, and the structures expressed by the Formula (3) may or may not be continuous with each other.

R2 in the Formula (2) includes at least one of a glycidyl group or an epoxidized alkyl group which is selected from the group consisting of a hydrogen atom, an alkyl group, the glycidyl group, and the epoxidized alkyl group. It will be described supplementally what this limitation means. As a premise, there is one R2 in one structure expressed by the Formula (2). A situation where the acrylic resin has only one structure expressed by the Formula (2) and a situation where the acrylic resin has two or more structures expressed by the Formula (2) will be described separately.

In the former case, i.e., if the acrylic resin has one structure expressed by the Formula (2), R2 is either a glycidyl group or an epoxidized alkyl group.

In the latter case, i.e., if the acrylic resin has two or more structures expressed by the Formula (2), R2 in at least one of the structures expressed by the Formula (2) is either a glycidyl group or an epoxidized alkyl group, while R2 in the other structure(s) expressed by the Formula (2) is either a hydrogen atom or an alkyl group. Since R2 in the at least one structure expressed by the Formula (2) is either a glycidyl group or an epoxidized alkyl group, R2 in all the structures expressed by the Formula (2) may be a glycidyl group or an epoxidized alkyl group.

The structure expressed by the Formula (3) has Ph (phenyl group), —COOCH₂Ph, and —COO(CH₂)₂Ph. Since Ph, —COOCH₂Ph, and —COO(CH₂)₂Ph are thermally stable, the strength of the cured product of the resin composition may be increased, and therefore, the laminate (metal-clad laminate 4 and printed wiring board 5) may have their heat resistance increased.

The high-molecular-weight substance (E) is a substance having a weight average molecular weight (Mw) equal to or greater than 10,000 and equal to or less than 900,000, preferably equal to or greater than 10,000 and equal to or less than 600,000. The high-molecular-weight substance (E) also makes it easier to impart impact resistance and toughness to the cured product of the resin composition without sacrificing heat resistance.

Note that the high-molecular-weight substance (E) does not include the curable resin (B) or the core-shell rubber (D).

### <Other Components (F)>

The other components (F) are components other than the molybdenum compound (A), the curable resin (B), the inorganic filler (C), the core-shell rubber (D), and the high-molecular-weight substance (E). Specific examples of the other components (F) include, without limitation, epoxy resins, phosphorus-based flame retardants, curing accelerators, polymerization initiators, additives, and solvents.

Examples of the epoxy resins include bisphenol epoxy resins, novolac epoxy resins, biphenyl epoxy resins, xylylene epoxy resins, aryl-alkylene epoxy resins, naphthalene epoxy resins, triphenylmethane epoxy resins, anthracene epoxy resins, dicyclopentadiene epoxy resins, norbornene epoxy resins, and fluorene epoxy resins.

Examples of the phosphorus-based flame retardant include, without limitation, phosphine oxide compounds (xylylene bisdiphenylphosphine oxide), and phosphaphenanthrene phosphorus compounds. Among the phosphaphenanthrene phosphorus compounds, a phosphaphenanthrene phosphorus compound having a reactive unsaturated group (for example, product name “SD-5” manufactured by SANKO Inc.) is particularly preferred.

The curing accelerator contains an imidazole compound. Examples of the imidazole compound include, without limitation, 2-ethyl-4-methylimidazole.

Examples of the polymerization initiator include, without limitation, α,α′-di(t-butylperoxy) diisopropylbenzene.

Examples of the additives include, without limitation, coupling agents and dispersants.

Examples of the solvent include, without limitation, methyl ethyl ketone (MEK). By adjusting the amount of the solvent, the resin composition may be turned into a varnish.

### <Quantitative Relationship Between Components>

The total content of the molybdenum compound (A) and the inorganic filler (C) is preferably equal to or greater than 30 parts by mass and equal to or less than 70 parts by mass, and more preferably equal to or greater than 45 parts by mass and equal to or less than 67 parts by mass, with respect to 100 parts by mass of the resin composition. Setting the total content of the molybdenum compound (A) and the inorganic filler (C) at a value equal to or greater than 30 parts by mass makes it easier to achieve a low coefficient of thermal expansion. Setting the total content of the molybdenum compound (A) and the inorganic filler (C) at a value equal to or less than 70 parts by mass may reduce the chances of causing a decline in adhesive strength to the metal layer (such as a sheet of copper foil).

The content of the molybdenum compound (A) is preferably equal to or greater than 0.5 parts by mass and equal to or less than 40 parts by mass, and more preferably equal to or greater than 2 parts by mass and equal to or less than 30 parts by mass, with respect to 100 parts by mass in total of the molybdenum compound (A) and the inorganic filler (C). Setting the content of the molybdenum compound (A) at a value equal to or greater than 0.5 parts by mass may reduce the chances of causing a decline in drillability. Setting the content of the molybdenum compound (A) at a value equal to or less than 40 parts by mass may reduce the chances of causing a decline in adhesive strength to the metal layer (such as a sheet of copper foil).

If the resin composition contains the core-shell rubber (D), then the content of the core-shell rubber (D) is preferably equal to or greater than 1 part by mass and equal to or less than 12 parts by mass, and more preferably equal to or greater than 3 parts by mass and equal to or less than 8 parts by mass, with respect to 100 parts by mass of the resin composition.

If the resin composition contains the high-molecular-weight substance (E), then the content of the high-molecular-weight substance (E) is preferably equal to or greater than 1 part by mass and equal to or less than 12 parts by mass, and more preferably equal to or greater than 3 parts by mass and equal to or less than 8 parts by mass, with respect to 100 parts by mass of the resin composition.

### (1.2) Manufacturing Methods

The resin composition according to this embodiment may be manufactured by at least two methods.

One of the at least two methods is a pretreatment method. According to the pretreatment method, molybdenum compound particles included in the molybdenum compound (A) are surface-treated with a surface treatment agent before being compounded with the other components. As used herein, the “other components” refer to the curable resin (B), the inorganic filler (C), the core-shell rubber (D), the high-molecular-weight substance (E), and the other components (F).

A second method is an integral blending method. According to the integral blending method, molybdenum compound particles included in the molybdenum compound (A) are not surface-treated yet before being compounded with the other components. That is to say, after the molybdenum compound (A), including non-surface-treated molybdenum compound particles, and a surface treatment agent have been compounded with the other components, the molybdenum compound (A) is surface-treated with the surface treatment agent by stirring up the compounded mixture.

### (2) Prepreg

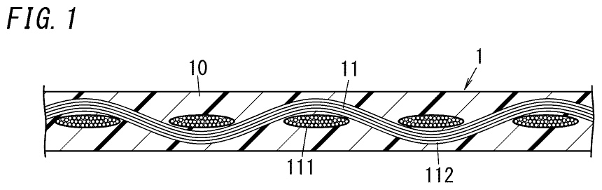

FIG. 1 illustrates a prepreg 1 according to this embodiment. The prepreg 1 may be used, for example, as a material for a printed wiring board 5. The prepreg 1 includes a base member 11 and a resin layer 10.

The base member 11 may be formed by, for example, plain weave. That is to say, the base member 11 is formed by weaving a warp 111 and a woof 112 crossing each other. The base member 11 may be, without limitation, a piece of glass cloth, for example. Examples of the glass fiber as a constituent material for the glass cloth include, without limitation, E glass, S glass, Q glass, T glass, TS glass, NE glass, and L glass. Among other things, S glass, Q glass, T glass, TS glass, NE glass, and L glass are particularly preferred from the viewpoint of low thermal expansibility. That is why the glass cloth preferably includes at least one glass fiber selected from the group consisting of S glass, Q glass, T glass, TS glass, NE glass, and L glass. Note that the thickness of the base member 11 is not limited to any particular value.

The resin layer 10 includes either the resin composition or a semi-cured product of the resin composition, each of which has been impregnated into the base member 11. As used herein, the semi-cured product of the resin composition refers to a resin composition in an intermediate stage (Stage B) of a curing reaction. Note that the thickness of the resin layer 10 is not limited to any particular value.

### (3) Film with Resin

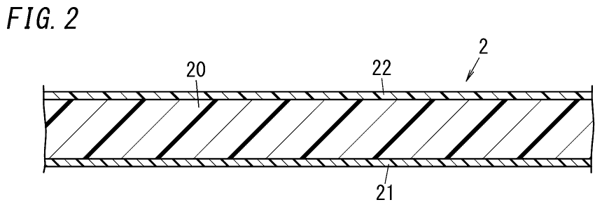

FIG. 2 illustrates a film 2 with resin according to this embodiment. The film 2 with resin may be used as a material in a buildup process, for example. The film 2 with resin includes a resin layer 20, a supporting film 21, and a protective film 22.

The resin layer 20 includes either the resin composition or a semi-cured product of the resin composition. Note that the thickness of the resin layer 20 is not limited to any particular value.

The supporting film 21 supports the resin layer 20 thereon. The supporting film 21 is temporarily fixed to one surface of the resin layer 20. The supporting film 21 may be peeled off from the resin layer 20 as needed.

The protective film 22 protects the resin layer 20. The protective film 22 is temporarily fixed to the other surface of the resin layer 20. The protective film 22 may be peeled off from the resin layer 20 as needed.

### (4) Sheet of Metal Foil with Resin

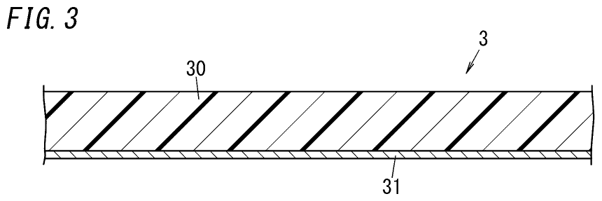

FIG. 3 illustrates a sheet of metal foil 3 with resin according to this embodiment. The sheet of metal foil 3 with resin may be used as a material in a buildup process, for example. The sheet of metal foil 3 with resin includes a resin layer 30 and a sheet of metal foil 31.

The resin layer 30 contains either the resin composition or a semi-cured product of the resin composition. Note that the thickness of the resin layer 30 is not limited to any particular value.

The sheet of metal foil 31 is bonded to one surface of the resin layer 30. The sheet of metal foil 31 may be, without limitation, a sheet of copper foil, for example.

### (5) Metal-Clad Laminate

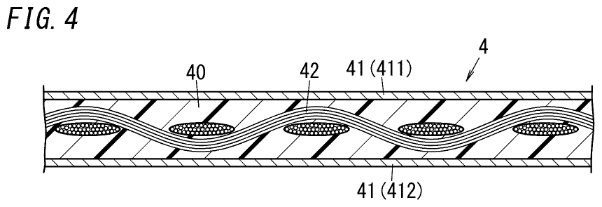

FIG. 4 illustrates a metal-clad laminate 4 according to this embodiment. The metal-clad laminate 4 may be used as a material for a printed wiring board 5. The metal-clad laminate 4 includes an insulating layer 40 and at least one metal layer 41.

The insulating layer 40 includes either a cured product of the resin composition or a cured product of the prepreg 1. The insulating layer 40 is a layer with electrical insulation properties. Note that the thickness of the insulating layer 40 is not limited to any particular value.

The at least one metal layer 41 is bonded to the insulating layer 40. In this embodiment, the at least one metal layer 41 includes a first metal layer 411 and a second metal layer 412. The first metal layer 411 is bonded to one surface of the insulating layer 40. The second metal layer 412 is bonded to the other surface of the insulating layer 40. That is to say, the metal-clad laminate 4 shown in FIG. 4 is a double-sided metal-clad laminate. Either the first metal layer 411 or the second metal layer 412 may be omitted from the metal-clad laminate 4. In that case, the metal-clad laminate 4 is a single-sided metal-clad laminate.

### (6) Printed Wiring Board

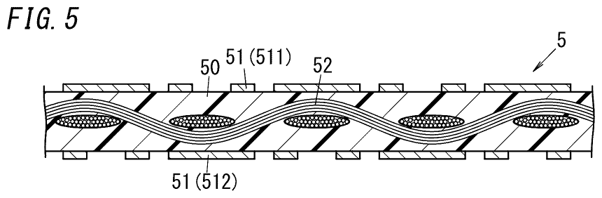

FIG. 5 illustrates a printed wiring board 5 according to this embodiment. Electronic components (not shown) are mounted on the printed wiring board 5, thereby forming a printed circuit assembly thereon. The printed wiring board 5 plays the role of physically supporting the electronic components thereon. The printed wiring board 5 includes an insulating layer 50 and conductor wiring 51.

The insulating layer 50 includes either a cured product of the resin composition or a cured product of the prepreg 1. The insulating layer 50 is a layer with electrical insulation properties. Note that the thickness of the insulating layer 50 is not limited to any particular value.

The conductor wiring 51 is provided to form an electronic circuit by electrically connecting the electronic components together. The conductor wiring 51 is formed on the insulating layer 50. In this embodiment, the printed wiring board 5 includes two layers, each including the conductor wiring 51. That is to say, the conductor wiring 51 includes first conductor wiring 511 and second conductor wiring 512. The first conductor wiring 511 is formed on one surface of the insulating layer 50. The second conductor wiring 512 is formed on the other surface of the insulating layer 50. Optionally, the first conductor wiring 511 and the second conductor wiring 512 may be interconnected to each other.

The printed wiring board 5 may include three or more layers, each including the conductor wiring 51. That is to say, the printed wiring board 5 may be a multilayer printed wiring board.

### 3. Aspects

As can be seen from the foregoing description of exemplary embodiments, the present disclosure has the following aspects. In the following description, reference signs are added in parentheses to the respective constituent elements solely for the purpose of clarifying the correspondence between those aspects of the present disclosure and the exemplary embodiments described above.

A first aspect is a resin composition, which contains: a molybdenum compound (A); a curable resin (B) including a maleimide compound (B1) and an allyl-group-containing benzoxadine compound (B2); and an inorganic filler (C). The molybdenum compound (A) includes molybdenum compound particles to be surface-treated with a surface treatment agent.

This aspect contributes to forming a cured product with excellent low thermal expansibility, heat resistance, adhesive strength, and drillability.

A second aspect is a resin composition which may be implemented in conjunction with the first aspect. In the second aspect, a ratio by mass (B2/B1) of the allyl-group-containing benzoxadine compound (B2) to the maleimide compound (B1) is equal to or greater than 0.3 and equal to or less than 1.0.

According to this aspect, setting the ratio by mass (B2/B1) at a value equal to or greater than 0.3 may reduce the chances of causing a decline in adhesive strength with respect to the metal layer (such as a sheet of copper foil). This may also reduce the chances of causing a decline in drillability. In addition, setting the ratio by mass (B2/B1) at a value equal to or less than 1.0 may also reduce the chances of causing a decrease in glass transition temperature (Tg).

A third aspect is a resin composition which may be implemented in conjunction with the first or second aspect. In the third aspect, the resin composition further contains at least one of core-shell rubber (D) or a high-molecular-weight substance (E) having a weight average molecular weight equal to or greater than 10,000 and equal to or less than 900,000.

This aspect makes it easier to impart impact resistance and toughness to a cured product of the resin composition without sacrificing the heat resistance.

A fourth aspect is a resin composition which may be implemented in conjunction with the third aspect. In the fourth aspect, the high-molecular-weight substance (E) contains at least one selected from the group consisting of acrylic resins, styrene copolymers, and butadiene copolymers.

This aspect makes it easier to impart impact resistance and toughness to a cured product of the resin composition without sacrificing the heat resistance.

A fifth aspect is a resin composition which may be implemented in conjunction with any one of the first to fourth aspects. In the fifth aspect, the molybdenum compound (A) includes spherical particles.

This aspect may improve the moldability of the resin composition.

A sixth aspect is a resin composition which may be implemented in conjunction with any one of the first to fifth aspects. In the sixth aspect, the molybdenum compound (A) has a 50% volume average particle size equal to or greater than 0.1 μm and equal to or less than 2.0 μm.

This aspect may improve the moldability of the resin composition.

A seventh aspect is a resin composition which may be implemented in conjunction with any one of the first to sixth aspects. In the seventh aspect, the surface treatment agent includes at least one compound selected from the group consisting of fluorene compounds, phenylamino silane compounds, styryl silane compounds, triphenylphosphine compounds, methacrylic silane compounds, epoxy silane compounds, isocyanate compounds, vinyl silane compounds, and silicone compounds.

This aspect may further increase the adhesive strength of a cured product of the resin composition.

An eighth aspect is a resin composition which may be implemented in conjunction with the seventh aspect. In the eighth aspect, the fluorene compound includes at least one selected from the group consisting of 9,9-bis[3-(triC1-4alkoxysilylC2-4alkylthio) propoxyphenyl]fluorene and 9,9-bis[3-(triC1-4alkoxysilylC2-4alkylthio) propoxy-C1-4alkylphenyl]fluorene.

This aspect may further increase the adhesive strength of a cured product of the resin composition.

A ninth aspect is a resin composition which may be implemented in conjunction with any one of the first to eighth aspects. In the ninth aspect, the inorganic filler (C) contains at least one compound selected from the group consisting of silica, talc, boehmite, magnesium hydroxide, aluminum hydroxide, and tungsten compounds.

This aspect makes it easier to decrease the coefficient of thermal expansion of a cured product of the resin composition.

A tenth aspect is a resin composition which may be implemented in conjunction with any one of the first to ninth aspects. In the tenth aspect, a total content of the molybdenum compound (A) and the inorganic filler (C) is equal to or greater than 30 parts by mass and equal to or less than 70 parts by mass with respect to 100 parts by mass of the resin composition.

According to this aspect, setting the total content of the molybdenum compound (A) and the inorganic filler (C) at a value equal to or greater than 30 parts by mass makes it easier to lower the coefficient of thermal expansion. In addition, setting the total content of the molybdenum compound (A) and the inorganic filler (C) at a value equal to or less than 70 parts by mass may reduce the chances of causing a decline in adhesive strength to a metal layer (such as a sheet of copper foil).

An eleventh aspect is a resin composition which may be implemented in conjunction with any one of the first to tenth aspects. In the eleventh aspect, the content of the molybdenum compound (A) is equal to or greater than 0.5 parts by mass and equal to or less than 40 parts by mass with respect to 100 parts by mass in total of the molybdenum compound (A) and the inorganic filler (C).

According to this aspect, setting the content of the molybdenum compound (A) at a value equal to or greater than 0.5 parts by mass may reduce the chances of causing a decline in drillability. In addition, setting the content of the molybdenum compound (A) at a value equal to or less than 40 parts by mass may reduce the chances of causing a decline in adhesive strength to a metal layer (such as a sheet of copper foil).

A twelfth aspect is a prepreg (1), which includes: a base member (11); and a resin layer (10) including either the resin composition according to any one of the first to eleventh aspects or a semi-cured product of the resin composition. The resin composition or the semi-cured product of the resin composition is impregnated into the base member (11).

This aspect contributes to forming a cured product with excellent low thermal expansibility, heat resistance, adhesive strength, and drillability.

A thirteenth aspect is a film (2) with resin, which includes: a resin layer (20) including either the resin composition according to any one of the first to eleventh aspects or a semi-cured product of the resin composition; and a supporting film (21) supporting the resin layer (20) thereon.

This aspect contributes to forming a cured product with excellent low thermal expansibility, heat resistance, adhesive strength, and drillability.

A fourteenth aspect is a sheet of metal foil (3) with resin, which includes: a resin layer (30) including either the resin composition according to any one of the first to eleventh aspects or a semi-cured product of the resin composition; and a sheet of metal foil (31) bonded to the resin layer (30).

This aspect contributes to forming a cured product with excellent low thermal expansibility, heat resistance, adhesive strength, and drillability.

A fifteenth aspect is a metal-clad laminate (4), which includes: an insulating layer (40) including either a cured product of the resin composition according to any one of the first to eleventh aspects or a cured product of the prepreg (1) according to the twelfth aspect; and a metal layer (41) bonded to the insulating layer (40).

This aspect contributes to forming a cured product with excellent low thermal expansibility, heat resistance, adhesive strength, and drillability.

A sixteenth aspect is a printed wiring board (5), which includes: an insulating layer (50) including either a cured product of the resin composition according to any one of the first to eleventh aspects or a cured product of the prepreg (1) according to the twelfth aspect; and conductor wiring (51) formed on the insulating layer (50).

This aspect contributes to forming a cured product with excellent low thermal expansibility, heat resistance, adhesive strength, and drillability.

### Examples

Next, the present disclosure will be described by way of illustrative examples. Note that the examples to be described below are only examples of the present disclosure and should not be construed as limiting.

### 1. Sample

### (1) Resin Composition

### (1.1) Materials

### <Molybdenum Compound (A)>

### <<Surface-Untreated>>

Zinc molybdate, product name “Z4SX” manufactured by Admatechs, having a spherical shape, D50 of 0.8 μm, and D90 of 1.2 μm.

### <<Surface Treatment Agent>>

Silane coupling agent (fluorene-based silane coupling agent), product name “OGSOL SC-001” manufactured by Osaka Gas Chemicals Co., Ltd.; and
Silane coupling agent (N-phenyl-3-aminopropyl trimethoxy silane), product name “KBM-573” manufactured by Shin-Etsu Chemical Co., Ltd.

### <<Surface-Treated>>

Zinc molybdate surface-treated with silane coupling agent (phenylamino silane compound), product name “Z4SX-A1” manufactured by Admatechs, having a spherical shape, D50 of 0.8 μm, and D90 of 1.2 μm.

### <Curable Resin (B)>

### <<Maleimide Compound (B1)>>

Compound expressed by Formula (b1-1), product name “BMJ-2300” manufactured by Daiwa Fine Chemicals Co., Ltd.; and
Compound expressed by Formula (b1-2), product name “BMI-689” manufactured by Designer Molecules Inc.

### <<Allyl-Group-Containing Benzoxazine Compound (B2)>>

Product name “ALP-D” manufactured by Shikoku Chemicals Corporation.

### <<Allyl-Group-Free Benzoxazine Compound>>

Benzoxazine compound containing no allyl group, product name “Pd” manufactured by Shikoku Chemicals Corporation.

### <<Phenolic Resin (B3)>>

Novolac phenolic resin, product name “TD-2090” manufactured by DIC Corporation, having a hydroxyl equivalent of 105 g/eq.

### <Inorganic Filler (C)>

Silica, product name “SC2050-MTX” manufactured by Admatechs, having D50 of 0.5 μm; and
Magnesium hydroxide, product name “EP1-S” manufactured by Konoshima Chemical Co., Ltd., having D50 of 2.0 μm.

### <Core-Shell Rubber (D)>

Silicone-acrylic composite rubber, product name “SRK200A” manufactured by Mitsubishi Chemical Group Corporation, having D50 of 0.1 μm.

### <High-Molecular-Weight Substance (E)>

Acrylic resin having structure expressed by Formulae (1), (2), and (3), product name “PASR001” manufactured by Nagase ChemteX Corporation, having a weight average molecular weight of 500,000.

### <Other Components (F)>

### <<Imidazole Compound>>

2-Ethyl-4-methylimidazole, product name “2E4MZ” manufactured by Shikoku Chemicals Corporation.

### <<Polymerization Initiator>>

α,α′-di(t-butylperoxy) diisopropylbenzene, product name “Perbutyl P” manufactured by NOF Corporation.

### (1.2) Manufacturing

In Examples 1-6, the pretreatment method was employed. That is to say, a surface-treated molybdenum compound (A) was used. A resin composition in the form of varnish was manufactured by compounding the respective components at the compounding ratio (parts by mass) shown in the following Table 1.

In Examples 7 and 8, the integral blending method was adopted. That is to say, a surface-untreated molybdenum compound (A) and a surface treatment agent were used. A resin composition was manufactured in the form of varnish in the same way as in Examples 1-6 except that the integral blending method was employed instead of the pretreatment method.

In Comparative Examples 1 and 2, a resin composition was manufactured in the form of varnish in the same way as in Examples 1-8 except that neither the pretreatment method nor the integral blending method was employed.

In Comparative Example 3, a resin composition was manufactured in the form of varnish in the same way as in Examples 1-8 except that an allyl-group-free benzoxadine compound was used instead of the allyl-group-containing benzoxadine compound (B2).

### (2) Prepreg

A prepreg was manufactured by impregnating the above-described resin composition into a piece of glass cloth (T glass, #2118 type, WTX2116T manufactured by Nitto Boseki Co., Ltd.) and then heating and drying the glass cloth at 130-150° C. for about 2-5 minutes.

### (3) Metal-Clad Laminate

Eight prepregs, each having the above-described structure, were stacked one on top of another, a sheet of copper foil (with a thickness of 12 μm) was laid on each side of the stack thus formed, and then the assembly thus formed was heated to 220° C. under a pressure of 3 MPa for two hours. In this manner, a metal-clad laminate having a sheet of copper foil bonded to each side thereof (i.e., a copper-clad laminate with a thickness of 0.8 mm) was manufactured.

### 2. Evaluations

### (1) Coefficient of Thermal Expansion

An evaluation board (unclad board) was obtained by etching away the sheets of copper foil from both sides of the metal-clad laminate. The coefficient of thermal expansion of the evaluation board was measured in an in-plane direction with a thermo-mechanical analyzer (model TMA/SS7100 manufactured by Hitachi High-Tech Science Corporation). The measurement mode was a compression mode. The temperature range was from 30° C. to 260° C. The temperature rise rate was 10° C./min. The load was 9.8 mN.

### (2) Glass Transition Temperature (Tg)

The glass transition temperature (Tg) of the evaluation board (unclad board) was measured using a viscoelasticity spectrometer (model DMS 100 manufactured by Seiko Instruments, Inc.). Specifically, a dynamic mechanical analysis (DMA) was carried out using a bending module with the frequency set at 10 Hz. The temperature at which tan δ reached a local maximum when the temperature was increased from room temperature to 360° C. at a temperature increase rate of 5° C./min was defined to be the glass transition temperature (Tg).

### (3) Copper Foil Peel Strength

The copper foil peel strength of the metal-clad laminate was measured in compliance with the JIS C 6481 standard. Specifically, the sheet of copper foil was removed entirely from one surface of the metal-clad laminate but a rectangular sheet of copper foil having a width of 10 mm and a length of 100 mm left on the one surface. Then, the rectangular sheet of copper foil was peeled off at a rate of 50 mm/min using a tensile tester and the peel strength at that time was measured as the copper foil peel strength.

### (4) Drillability

The drillability was rated by hole position accuracy. Specifically, using a printed circuit board drilling machine (model “ND-1A221L” manufactured by Viamechanics), drilling was performed on an evaluation board (stack of two metal clad laminates) to measure the degree of positional misalignment between the holes thus drilled. The hole position accuracy (unit: μm) was determined by calculating the sum of an average value of the degree of positional misalignment between the holes at the time of 20,000 hits and 3σ (σ: standard deviation).

TABLE 1

| | | | Examples | | | | | | | | Comparative Examples | | |
|---|---|---|---|---|---|---|---|---|---|---|---|---|---|
| | | | 1 | 2 | 3 | 4 | 5 | 6 | 7 | 8 | 1 | 2 | 3 |
| Component | Surface-untreated | Z4SX | 0 | 0 | 0 | 0 | 0 | 0 | 58 | 58 | 0 | 58 | 0 |
| (A) | Surface treatment | OGSOL | 0 | 0 | 0 | 0 | 0 | 0 | 1.5 | 0 | 0 | 0 | 0 |
| | agent | SC-001 | | | | | | | | | | | |
| | | KBM-573 | 0 | 0 | 0 | 0 | 0 | 0 | 0 | 1.5 | 0 | 0 | 0 |
| | Surface-treated | Z4SX-A1 | 58 | 58 | 58 | 58 | 58 | 58 | 0 | 0 | 0 | 0 | 58 |
| Component | Component (B1) | BMI-2300 | 56 | 28 | 35 | 49 | 49 | 49 | 49 | 49 | 49 | 49 | 49 |
| (B) | | BMI-689 | 10 | 10 | 10 | 10 | 10 | 10 | 10 | 10 | 10 | 10 | 10 |
| | Component (B2) | ALP-D | 14 | 42 | 35 | 21 | 21 | 21 | 21 | 21 | 21 | 21 | 0 |
| | Ally-group-free | Pd | 0 | 0 | 0 | 0 | 0 | 0 | 0 | 0 | 0 | 0 | 21 |
| | benzoxazine | | | | | | | | | | | | |
| | compound | | | | | | | | | | | | |
| | Component (B3) | TD-2090 | 5 | 5 | 5 | 5 | 5 | 5 | 5 | 5 | 5 | 5 | 5 |
| Component (C) | | SC2050- | 154 | 154 | 154 | 154 | 154 | 120 | 154 | 154 | 183 | 154 | 154 |
| | | MTX | | | | | | | | | | | |
| | | EP1-S | 0 | 0 | 0 | 0 | 0 | 34 | 0 | 0 | 0 | 0 | 0 |
| Component (D) | | SRK200A | 0 | 0 | 0 | 0 | 20 | 0 | 0 | 0 | 0 | 0 | 0 |
| Component (E) | | PASR001 | 20 | 20 | 20 | 20 | 0 | 20 | 20 | 20 | 20 | 20 | 20 |
| Component (F) | | 2E4MZ | 1 | 1 | 1 | 1 | 1 | 1 | 1 | 1 | 1 | 1 | 1 |
| | | Perbutyl P | 1 | 1 | 1 | 1 | 1 | 1 | 1 | 1 | 1 | 1 | 1 |
| (B2/B1) | | — | 0.21 | 1.11 | 0.78 | 0.36 | 0.36 | 0.36 | 0.36 | 0.36 | 0.36 | 0.36 | 0.36 |
| Evaluation | Coefficient of | ppm/° C. | 5.9 | 5.6 | 5.3 | 5.8 | 5.9 | 5.9 | 5.8 | 5.7 | 5.7 | 5.8 | 6.4 |
| results | thermal expansion | | | | | | | | | | | | |
| | (in-plane | | | | | | | | | | | | |
| | direction) | | | | | | | | | | | | |
| | Glass transition | ° C. | 351 | 278 | 305 | 338 | 338 | 335 | 340 | 337 | 340 | 341 | 302 |
| | temperature (Tg) | | | | | | | | | | | | |
| | Copper foil peel | kN/cm² | 0.5 | 0.6 | 0.58 | 0.55 | 0.53 | 0.52 | 0.54 | 0.55 | 0.51 | 0.44 | 0.54 |
| | strength | | | | | | | | | | | | |
| | Drillability | μm | 38 | 24 | 26 | 29 | 33 | 27 | 27 | 28 | Broken | 36 | 29 |

In Examples 1-8, favorable results were achieved in low thermal expansibility, heat resistance, adhesive strength, and drillability.

On the other hand, in Comparative Example 1, the drillability was poor and the drill was broken. In Comparative Example 2, the adhesive strength was low. In Comparative Example 3, the coefficient of thermal expansion increased.

### REFERENCE SIGNS LIST

1 Prepreg
10 Resin Layer
11 Base Member
2 Film with Resin
20 Resin Layer
21 Supporting Film
3 Sheet of Metal Foil with Resin
30 Resin Layer
31 Sheet of Metal Foil
4 Metal-Clad Laminate
40 Insulating Layer
41 Metal Layer
5 Printed Wiring Board
50 Insulating Layer
51 Conductor Wiring

1. A resin composition containing:
a molybdenum compound (A);
a curable resin (B) including a maleimide compound (B1) and an allyl-group-containing benzoxadine compound (B2); and
an inorganic filler (C),
the molybdenum compound (A) including molybdenum compound particles to be surface-treated with a surface treatment agent.

2. The resin composition of claim 1, wherein
a ratio by mass (B2/B1) of the allyl-group-containing benzoxadine compound (B2) to the maleimide compound (B1) is equal to or greater than 0.3 and equal to or less than 1.0.

3. The resin composition of claim 1, further containing at least one of core-shell rubber (D) or a high-molecular-weight substance (E) having a weight average molecular weight equal to or greater than 10,000 and equal to or less than 900,000.

4. The resin composition of claim 3, wherein
the high-molecular-weight substance (E) contains at least one selected from the group consisting of acrylic resins, styrene copolymers, and butadiene copolymers.

5. The resin composition of claim 1, wherein
the molybdenum compound (A) includes spherical particles.

6. The resin composition of claim 1, wherein
the molybdenum compound (A) has a 50% volume average particle size equal to or greater than 0.1 m and equal to or less than 2.0 m.

7. The resin composition of claim 1, wherein
the surface treatment agent includes at least one compound selected from the group consisting of fluorene compounds, phenylamino silane compounds, styryl silane compounds, triphenylphosphine compounds, methacrylic silane compounds, epoxy silane compounds, isocyanate compounds, vinyl silane compounds, and silicone compounds.

8. The resin composition of claim 7, wherein
the fluorene compound includes at least one selected from the group consisting of 9,9-bis[3-(triC1-4alkoxysilylC2-4alkylthio) propoxyphenyl]fluorene and 9,9-bis[3-(triC1-4alkoxysilylC2-4alkylthio) propoxy-C1-4alkylphenyl]fluorene.

9. The resin composition of claim 1, wherein
the inorganic filler (C) contains at least one compound selected from the group consisting of silica, talc, boehmite, magnesium hydroxide, aluminum hydroxide, and tungsten compounds.

10. The resin composition of claim 1, wherein
a total content of the molybdenum compound (A) and the inorganic filler (C) is equal to or greater than 30 parts by mass and equal to or less than 70 parts by mass with respect to 100 parts by mass of the resin composition.

11. The resin composition of claim 1, wherein
content of the molybdenum compound (A) is equal to or greater than 0.5 parts by mass and equal to or less than 40 parts by mass with respect to 100 parts by mass in total of the molybdenum compound (A) and the inorganic filler (C).

12. A prepreg comprising: a base member: and a resin layer including either the resin composition of claim 1 or a semi-cured product of the resin composition, the resin composition or the semi-cured product of the resin composition being impregnated into the base member.

13. A film with resin comprising: a resin layer including either the resin composition of claim 1 or a semi-cured product of the resin composition; and a supporting film supporting the resin layer thereon.

14. A sheet of metal foil with resin, comprising: a resin layer including either the resin composition of claim 1 or a semi-cured product of the resin composition; and a sheet of metal foil bonded to the resin layer.

15. A metal-clad laminate comprising: an insulating layer including a cured product of the resin composition of claim 1; and a metal layer bonded to the insulating layer.

16. A printed wiring board comprising: an insulating layer including a cured product of the resin composition of claim 1; and conductor wiring formed on the insulating layer.
